(19) United States
(12) Patent Application Publication
(10) Pub. No.: US 2025/0120069 A1
(43) Pub. Date: Apr. 10, 2025

(54) SELF-ALIGNED BIT LINE FOR 4F2 DRAM

(71) Applicant: Applied Materials, Inc., Santa Clara, CA (US)

(72) Inventors: Zhijun CHEN, San Jose, CA (US); Fredrick FISHBURN, Aptos, CA (US); Balasubramanian PRANATHARTHIHARAN, San Jose, CA (US)

(73) Assignee: Applied Materials, Inc., Santa Clara, CA (US)

(21) Appl. No.: 18/905,062

(22) Filed: Oct. 2, 2024

Related U.S. Application Data
(60) Provisional application No. 63/588,214, filed on Oct. 5, 2023.

(51) Int. Cl. H10B 12/00

(52) U.S. Cl. CPC H10B 12/482; H10B 12/02; H10B 12/315; H10B 12/488

(57) ABSTRACT

The present technology includes vertical cell dynamic random-access memory (DRAM) arrays with improve bit line and storage node contact resistivity and self-alignment as well as methods of making such arrays. The arrays include a plurality of bit lines arranged in a first horizontal direction and a plurality of word lines arranged in a second horizontal direction. The arrays include a plurality of channels extending in a vertical direction that is generally orthogonal to the first direction and the second horizontal direction, such that the plurality of bit lines intersect with a source/drain region of the plurality of channels, and the plurality of word lines intersect with gate regions of the plurality of channels. In addition, arrays include where a bit line, a storage node contact, or both, are formed from a metallized material.

### CROSS-REFERENCES TO RELATED APPLICATIONS

This application claims the benefit of priority to U.S. Patent Application No. 63/588,214 filed Oct. 5, 2023, the contents of which are hereby incorporated by reference in their entirety for all purposes.

### TECHNICAL FIELD

This disclosure generally describes designs for a 4F² two-dimensional dynamic random-access memory array. More specifically, this disclosure describes a 4F² memory array with a self-aligned metallized bit line or storage node contacts.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. In the 4F² DRAM scheme, a storage node (capacitor) and bit line are located at the top and bottom of a vertical cell transistor, leaving the channel completely isolated from the body. Due to this arrangement, the floating body effect, which is not an issue for current 8F² or 6F² DRAM cell architecture due to the body connection of the channels, becomes a major technical challenge for 4F² DRAM. In addition, such an arrangement also interferes with formation of the bit line or storage node contact. Therefore, improvements in the art are needed.

### BRIEF SUMMARY

The present technology is generally directed to vertical cell dynamic random-access memory (DRAM) precursor structures, methods of making such structures, as well as semiconductor devices and methods of making such devices. DRAM precursor structures include a substrate, one or more sacrificial layers formed over the substrate, one or more first epitaxially grown junction material layers formed over the sacrificial layer, an epitaxially grown channel material formed over the first junction material, and one or more second epitaxially grown junction material layers formed over the channel material.

In embodiments, precursor structures include where the one or more sacrificial layers is epitaxially grown silicon germanium (SiGe). In more embodiments, germanium is present in the one or more sacrificial layers in an amount of greater than or about 5 wt. %. Furthermore, in embodiments, the one or more sacrificial layers has a thickness of greater than or about 5 nm. Additionally or alternatively, in embodiments, the one or more first epitaxially grown junction material layers, the one or more second epitaxially grown junction material layers, or both the one or more first epitaxially grown junction material layers and the one or more second epitaxially grown junction material layers have a dopant concentration at any point along or within a layer of the junction material that is greater than or about 50% of an average doping concentration of the respective layer of the junction material. In yet more embodiments, the one or more first epitaxially grown junction material layers includes n-doped silicon, the channel material includes silicon, and the one or more second epitaxially grown junction material layers includes n-doped silicon.

The present technology is also generally directed to methods of forming precursor structures. Methods include growing one or more sacrificial layers over a semiconductor substrate. Methods include epitaxially growing a channel material over the one or more sacrificial layers while providing one or more n-type dopants, forming one or more first junction layers. Methods include epitaxially growing the channel material over the one or more first junction layers, forming one or more channel layers. Methods include epitaxially growing the channel material over the one or more channel layers while providing one or more n-type dopants, forming one or more second junction layers.

In embodiments, methods include where the one or more sacrificial layers are grown to a height of greater than or about 10 nm. In more embodiments, the one or more sacrificial layers contains germanium at an amount of greater than or about 5 wt. % based upon the weight of the one or more sacrificial layers. Embodiments include where the one or more first junction layers, the one or more second junction layers, or both the one or more first junction layers and the one or more second junction layers have a target doping concentration, wherein a dopant concentration at any point along or within one or more of the first junction layers, the second junction layers, or both the first junction layer and the second junction layer is greater than or about 50% of a target doping concentration of the respective layer. Additionally or alternatively, in embodiments, the one or more channel layers are grown to a height of greater than or about 10nm.

The present technology is also generally directed to vertical cell DRAM arrays. Arrays include a plurality of metallized bit lines arranged in a first horizontal direction, a plurality of word lines arranged in a second horizontal direction, and a plurality of channels extending in a vertical direction. Arrays include where the vertical direction is generally orthogonal to the first horizontal direction and the second horizontal direction such that the plurality of metallized bit lines intersect with a source/drain region of the plurality of channels, and the plurality of word lines intersect with gate regions of the plurality of channels. Arrays include a dielectric material spacer disposed between adjacent bit lines of the plurality of bit lines.

In embodiments, arrays include that the dielectric material spacer comprises a dielectric oxide. In more embodiments, at least a portion of the metallized bit lines are offset from a respective channel of the plurality of channels by about 10% to less than or about 90% of a width of the respective channel. Additionally or alternatively, embodiments include where at least a portion of the dielectric material spacers at least partially intersect with a source/drain region of the plurality of channels. In yet mor embodiments, the bit line is a self-aligned bit line disposed below a single crystalline channel. Moreover, in embodiments, one or more metallized storage node contacts disposed on a top end of the plurality of channels.

The present technology is also generally directed to methods of forming vertical cell DRAM arrays. Methods include providing a substrate, having a sacrificial material over a substrate material, and one or more channel materials disposed over the sacrificial layer.

Methods include etching the substrate to form one or more shallow trench isolations and a plurality of vertically extending channels having at least a first source/drain region. Methods include forming a dielectric material in the one or more of the shallow trench isolations. Methods include removing at least a portion of the sacrificial material, forming a void space that at least partially intersects with a portion of the first source/drain region of the vertically extending channels, and forming a metallized bit line in the void space.

In embodiments, methods include forming a word line in a word line trench, where the word line intersects with a gate region of the plurality of vertically extending channels. In mor embodiments, methods include where the portion of the sacrificial material is removed through one or more access holes. In yet further embodiments, methods include where the portion of the sacrificial material is removed through an exposed region at a substrate backside or a side surface. In embodiments, methods include reducing a thickness of the substrate material prior to removing the at least a portion of the sacrificial material. Moreover, in embodiments, methods include removing all of the sacrificial material. Additionally or alternatively, in embodiments, the one or more channel materials include a doped channel material and an undoped channel material. In further embodiments, methods include forming one or more of the plurality of vertically extending channel by depositing a doped channel material over the sacrificial material, depositing an undoped channel material over the doped channel material, and depositing a second doped channel material over the undoped channel material. In more embodiments, methods include flipping the substrate, and removing all or a portion of the substrate prior to removing the sacrificial material. Furthermore, in embodiments, methods include siliciding the first source/drain region prior to forming the metallized bit line. In embodiments, the metallized bit line include tungsten, molybdenum, titanium, zirconium, nickel, hafnium, cobalt, tin, tantalum, platinum, iron, niobium, palladium, a metal-containing species thereof, alloys thereof, or combinations thereof.

The present technology is also generally directed to vertical cell DRAM arrays. Arrays include a plurality of bit lines arranged in a first horizontal direction, a plurality of word lines arranged in a second horizontal direction, and a plurality of channels extending in a vertical direction. Arrays include where the vertical direction is generally orthogonal to the first horizontal direction and the second horizontal direction such that the plurality of bit lines intersect with a source/drain region of the plurality of channels, and the plurality of word lines intersect with gate regions of the plurality of channels. Arrays include a plurality of metallized storage node contacts.

In embodiments, arrays include where the plurality of metallized storage node contacts are self-aligned below a single crystalline channel. In more embodiments, the plurality of bit lines include metallized bit lines disposed on a top end of the plurality of channels.

The present technology is also generally directed to methods for forming vertical cell DRAM arrays. Methods include providing a substrate having a sacrificial layer over a substrate material and one or more channel materials disposed over the sacrificial layer. Methods include etching the substrate to form one or more shallow trench isolations and a plurality of vertically extending channels having at least a first source/drain region. Methods include forming a dielectric material in the one or more of the shallow trench isolations. Methods include removing at least a portion of the sacrificial material, forming a void space that at least partially intersects with a portion of the first source/drain region of the vertically extending channels. Methods include forming one or more metallized storage node contacts in the void space.

In embodiments, methods include forming a word line in a word line trench, where the word line intersects with a gate region of the plurality of channels. In more embodiments, methods include forming one or more of the plurality of vertically extending channel by depositing a doped channel material over the sacrificial material, depositing an undoped channel material over the doped channel material, and depositing a second doped channel material over the undoped channel material. In yet more embodiments, methods include flipping the substrate, and removing all or a portion of the substrate prior to removing the sacrificial material. Furthermore, in embodiments, methods include siliciding the first source/drain region prior to forming the one or more metallized storge node contacts. Additionally or alternatively, embodiments include where the one or more metallized storage node contacts comprises tungsten, molybdenum, titanium, zirconium, nickel, hafnium, cobalt, tin, tantalum, platinum, iron, niobium, palladium, a metal-containing species thereof, alloys thereof, or combinations thereof.

Such technology may provide numerous benefits over conventional systems and

techniques. For example, the processes and systems may allow the formation of a bit line or a storage node contact junctions early in the process, significantly reducing the complexity and cost to form the junctions as compared to utilizing traditional approaches with thermal budget constraints. In additions, methods and systems discussed herein provide higher quality junctions for 4F² DRAM devices. Moreover, the processes and systems may allow the formation of a metallized bit line or storage node contact without additional overlay and patterning processes, instead providing a self-aligned metallized bit line or storage node contact. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a perspective view of a precursor semiconductor structure according to embodiments of the present technology with a sacrificial layer formed over a substrate.

FIG. 3B shows a perspective view of a precursor semiconductor structure according to embodiments of the present technology with a junction formed over a sacrificial layer.

FIG. 3C shows a perspective view of a precursor semiconductor structure according to embodiments of the present technology with a channel formed over the junction.

FIG. 3D shows a perspective view of a precursor semiconductor structure according to embodiments of the present technology with a junction formed over a channel.

FIG. 3E shows a perspective view of a precursor semiconductor structure according to embodiments of the present technology with a contact pad formed over a junction.

FIG. 4A shows a perspective view of a semiconductor structure according to embodiments of the present technology with one or more isolations.

FIG. 4B shows a perspective view of a semiconductor structure according to embodiments of the present technology with one or more isolations etched through a sacrificial layer.

FIG. 4C shows a perspective view of a semiconductor structure according to embodiments of the present technology with one or more isolations filled with an insulative material.

FIG. 4D shows a perspective view of a semiconductor structure according to embodiments of the present technology with one or more word line trenches.

FIG. 4E shows a perspective view of a semiconductor structure according to embodiments of the present technology with one or more 4F² features formed.

FIG. 4F shows a perspective view of a semiconductor structure according to embodiments of the present technology with the substrate flipped 180°.

FIG. 4G shows a perspective view of a semiconductor structure according to embodiments of the present technology with a metallize feature formed after removal of the sacrificial material.

FIG. 5A shows a perspective view of a semiconductor structure according to embodiments of the present technology with one or more word line trenches.

FIG. 5B shows a perspective view of a semiconductor structure according to embodiments of the present technology with one or more 4F² features formed.

FIG. 5C shows a perspective view of a semiconductor structure according to embodiments of the present technology with the substrate flipped 180°.

FIG. 5D shows a perspective view of a semiconductor structure according to embodiments of the present technology with a metallize feature formed after removal of the sacrificial material.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities were increasing by approximately 25% node over node. However, the node over node increase in bit density has trended down to approximate 20% over the more recent generations, mainly due to the challenges with scaling the cell area. Cell design architecture for modern DRAM technology has been based on 6F2 geometry, where F is the minimum feature size for a given technology node. Switching from 6F2 to 4F2 cell architecture could result in a 33% increase in bit density at the same technology node. In addition, patterning difficulties for 4F2 DRAM are greatly reduced as compared to 6F2. This is mainly because in the 4F2 DRAM scheme capacitor and bit line are located at two ends of a vertical cell transistor, instead of tightly packed on the same side as in 6F2 DRAM.

However, 4F2 DRAM design comes with its own challenges. For example, 4F2 memory cells have the transistor channel disposed between the bitline and the capacitor layers, so there is no common substrate connecting the channels, resulting in a floating body effect for these transistors. Moreover, such design schemes are also capable of producing high aspect ratio structures that challenge existing doping techniques.

In addition, when a capacitor is placed on top of a vertical channel, the bit line must be formed at the bottom of the vertical channel. This can be done by utilizing a continuous line of silicon as the bitline. However, silicon has high resistivity, particularly as compared to metal bit lines currently used in 6F2 DRAM. Alternatively, the bit line may be formed by patterning a metal bit line from the backside of the wafer after front side wafer bonding is complete, and the substrate has been flipped. However, such a process requires complex patterning and alignment, which proves challenging for processing throughput, as well as consistent high quality structure formation. For instance, such a process requires multiple complex masking and etching steps in order to align connections with the formed bitline. An alternative is to place the bit one on top of the vertical channel while forming the capacitor through back side processes after wafer bonding. However, similar to the issues experienced with bitline backside formation, such an alternative requires complex alignment and patterning of the storage node contacts to the vertical channels, which requires complex masking and etching steps in order to align the connections with the storage node contacts.

The present technology overcomes these and other problems by providing a method for forming a metallized bit line or storage node contact in a 4F² DRAM cell in a self-aligned manner. Namely, the present technology has surprisingly found that by providing a substrate having a unique orientation, a sacrificial material may be removed after frontside processing is complete, allowing the region to be filled with a metallized material which provides excellent resistivity for a bit line or storage node contact, as examples only. By utilizing such a sacrificial material, a metallized material may be filled into the void formed by the removed sacrificial material in a self-aligned manner. This allows a bit line or a storage node contact to be formed on a bottom of a semiconductor structure without requiring complex masking and etching operations. Moreover, the present technology also allows for the tailored doping of one or more source/drain regions when providing the substrate. Thus, the present technology may provide for highly specific and consistent dopant levels, even when the resulting dram cell contains one or more high aspect ratio or otherwise complex features.

Although the remaining disclosure will routinely identify specific deposition and etch processes utilized for forming vertical cell dynamic random-access memory (DRAM) arrays, such as a 4F² DRAM device, it will be readily understood that the systems and methods are equally applicable to other DRAM devices, other devices suffering from a floating body effect, and orientations thereof, as well as processes for forming such devices. Accordingly, the technology should not be considered to be so limited as for use with these specific devices or systems alone. The disclosure will discuss one possible semiconductor device that may include one or more components according to embodiments of the present technology before additional variations and adjustments to this apparatus according to embodiments of the present technology are described.

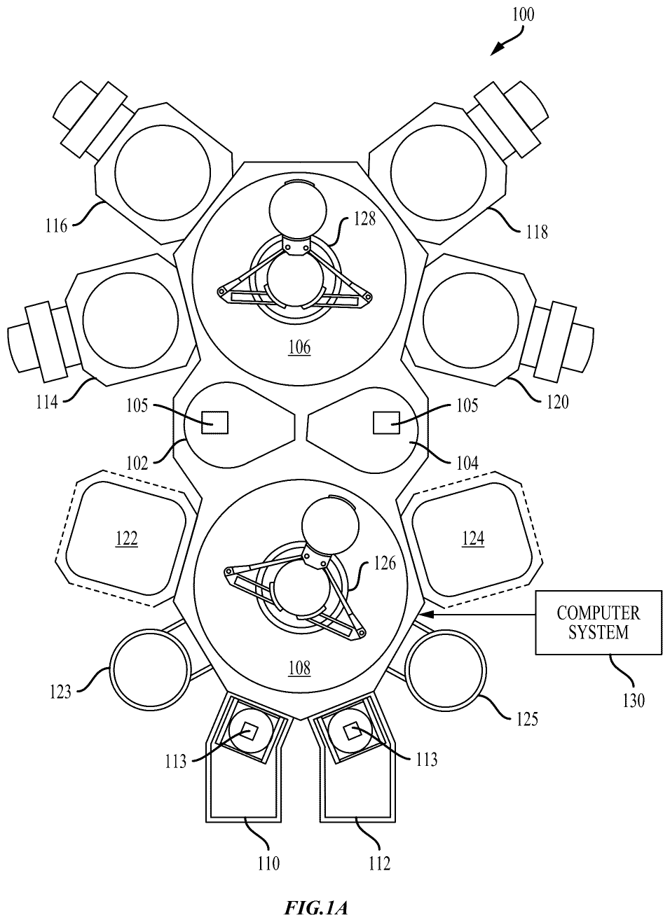

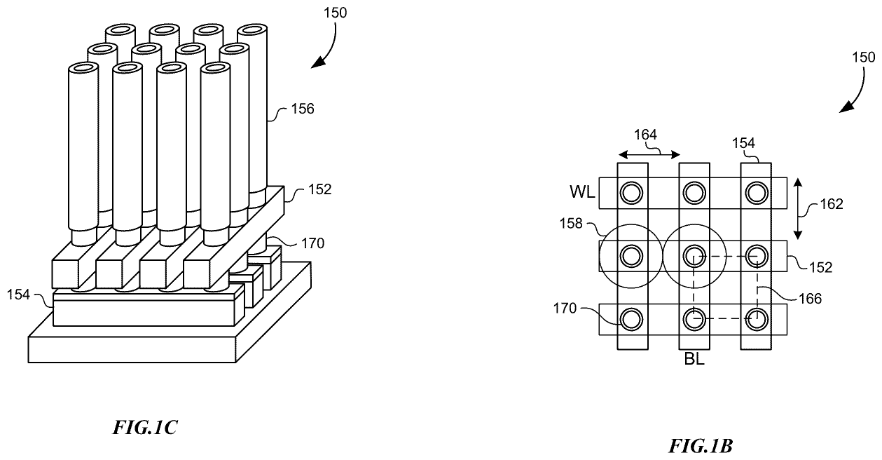

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and IC illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor 170, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular orthogonal grid pattern, it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

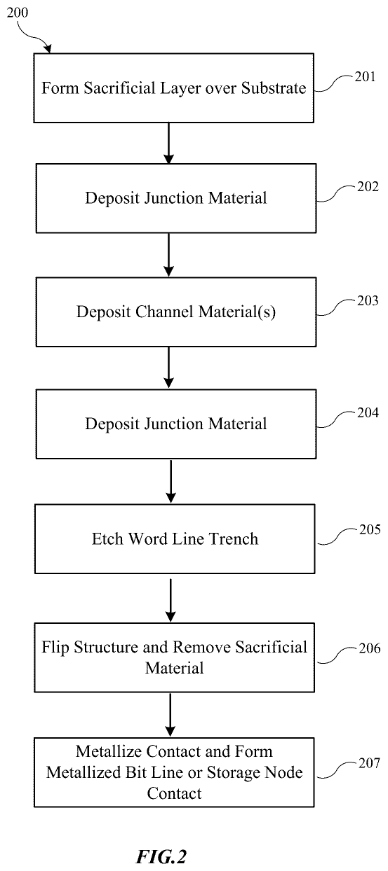

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically from the word line side of the structure to the bit line side of the structure, it should be understood that the other orientation from bit line to word line side may be utilized. In addition, while it should be clear that the precursor semiconductor structure 300 described herein may be utilized to advantageously form a variety of challenging structures, precursor structure 300, as well as semiconductor structure 400 and/or 500 may illustrate exemplary structures, and methods of forming such structures, only. Furthermore, it should be clear that these exemplary structures and methods of forming such structures are non-limiting and that further structures as well as methods of forming such structures are contemplated.

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed.

Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in the remaining figures, the illustrations of which will be described in conjunction with the operations of method 200. It is to be understood that the figures illustrate only partial schematic views, and a semiconductor substrate may include further components as illustrated in the figures, as well as alternative components, of any size or configuration that may still benefit from aspects of the present technology.

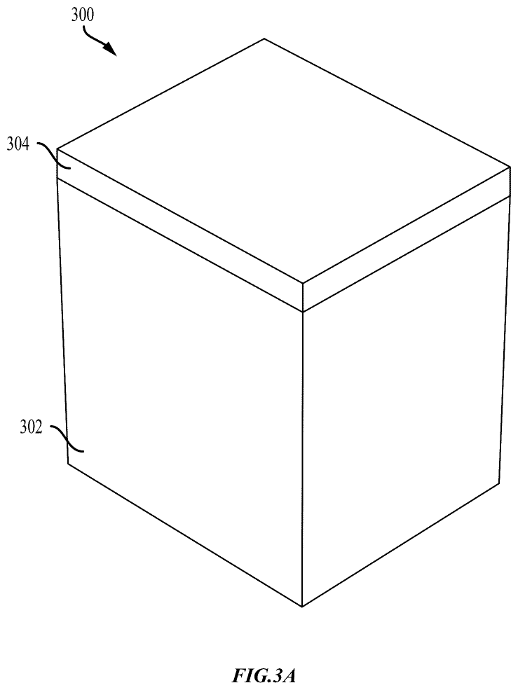

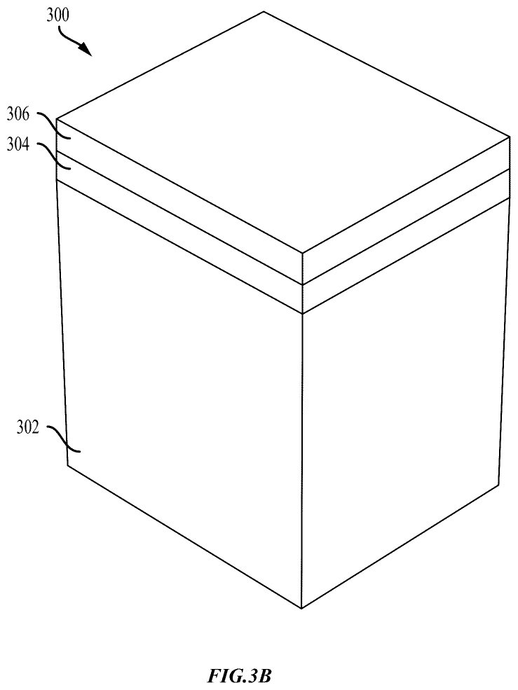

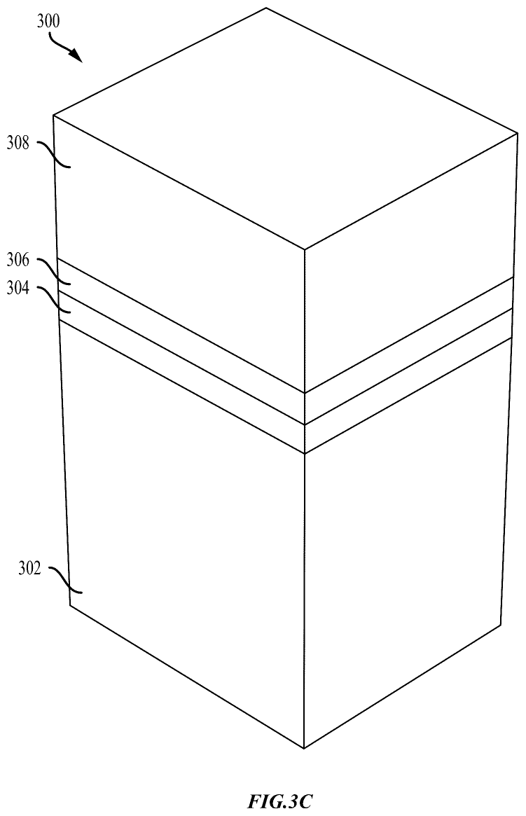

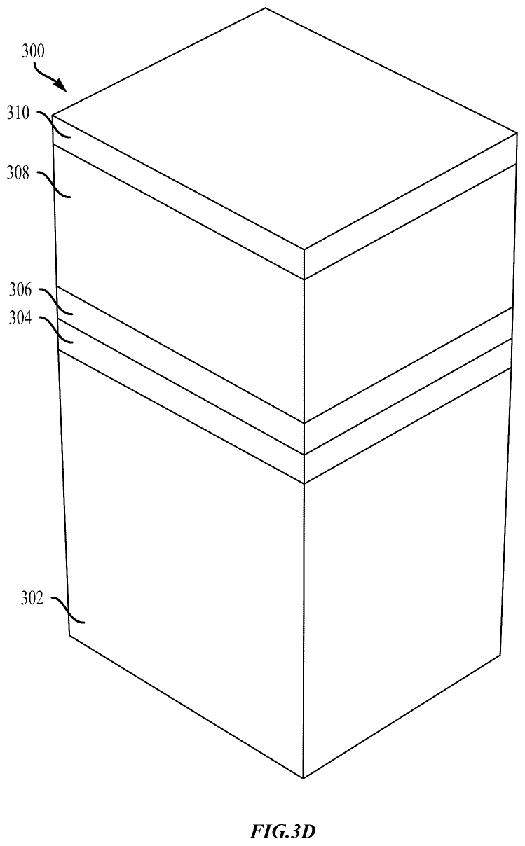

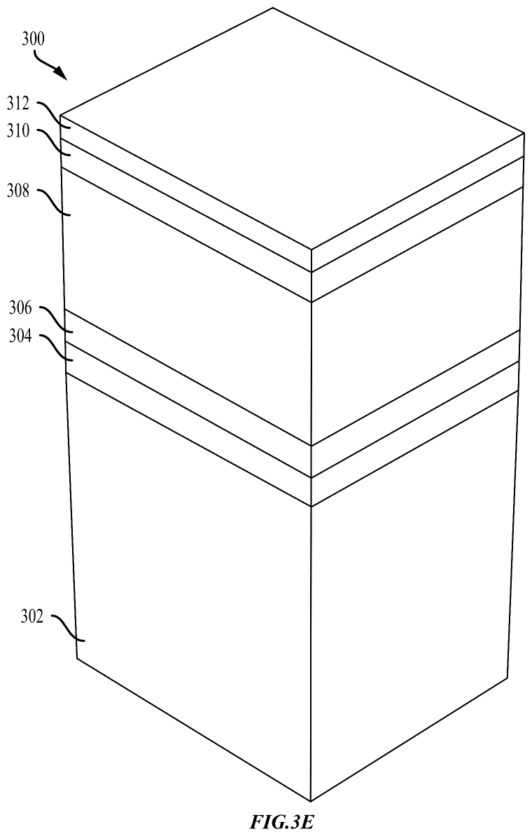

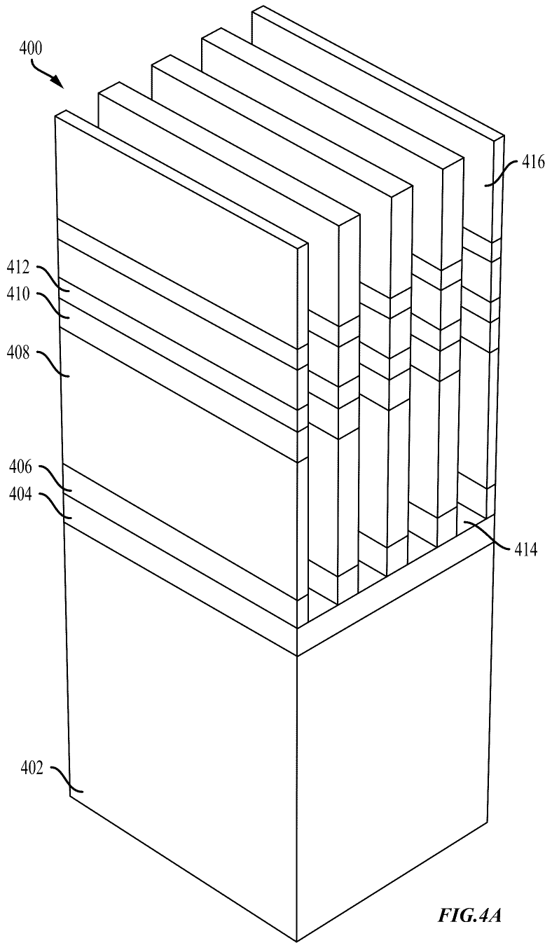

Method 200 may or may not involve optional operations to develop the semiconductor structure to a particular fabrication operation. It is to be understood that method 200 may be performed on any number of semiconductor structures 300 or substrates 302, as illustrated in the figures, including exemplary structures on which a selective deposition material may be formed. As illustrated in FIG. 3A substrate 302 may be any number of materials, such as a base wafer or substrate made of silicon or silicon-containing materials, germanium, other substrate materials, as well as one or more materials that may be formed overlying the substrate during semiconductor processing.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

In embodiments, the substrate 302 may include bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 302 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

As illustrated in FIG. 3A, structure 300 is provided that includes a substrate 302 that has a sacrificial layer 304 formed thereon at operation 201. In embodiments, the sacrificial layer 304, also referred to as a “sacrificial spacer” may be deposited or grown over substrate 302 in any manner as known in the art. In embodiments, the sacrificial material may be any material that can be selectively etched. For instance, in embodiments, the sacrificial material may be silicon germanium (SiGe) when silicon is utilized as the substrate, such as epitaxially grown SiGe. However, it should be clear that other combinations of materials having different etch selectivity as known in the art may also be utilized.

Namely, the present technology has surprisingly found that by forming a semiconductor structure 300 according to the methods and disclosure herein, the semiconductor structure 300 may be uniquely formed to allow for the self-aligned formation of one or more contacts on a bottom side of the structure 300. Namely, by initially forming a sacrificial spacer 304, the sacrificial spacer may retain the space necessary for one or more features. In addition, the sacrificial spacer may also serve as an etch stop in embodiments, providing for fully self-aligned features.

Nonetheless, when SiGe is utilized as the sacrificial layer 304 material, the germanium may be present in an amount of about 5 wt. % or greater, based upon the weight of the silicon and germanium in the SiGe, such as greater than or about 7.5 wt. %, such as greater than or about 10 wt. %, such as greater than or about 12.5 wt. %, such as greater than or about 15 wt. %, such as less than or about 25 wt. %, such as less than or about 22.5 wt. %, such as greater than or about 25 wt. %, such as greater than or about 27.5 wt. %, such as greater than or about 30 wt. %, such as greater than or about 32.5 wt. %, such a greater than or about 35 wt. %, such as greater than or about 37.5 wt. %, such as greater than or about 40 wt. %, such as greater than or about 42.5 wt. %, such as greater than or about 45 wt. %, such as greater than or about 47.5 wt. %, such as up to about 50 wt. %, or such as less than or about 50 wt. %, such as less than or about 40 wt. %, such as less than or about 35 wt. %, such as less than or about 30 wt. %, such as less than or about 25 wt. %, such as less than or about 20 wt. %, such as less than or about 17.5 wt. %, such as less than or about 15 wt. %, or any ranges or values therebetween.

Nonetheless, as the sacrificial layer 304 will serve as a placeholder for the later formed metallized feature, such as a bitline or storage node contact, the thickness or height of the sacrificial layer may be selected based upon the desired thickness or height of the resulting feature. Thus, in embodiments, the sacrificial layer may be deposited or grown to a thickness of greater than or about 5 nm, such as greater than or about 10 nm, such as greater than or about 15 nm, such as greater than or about 20 nm, such as greater than or about 25 nm, such as greater than or about 30 nm, such as greater than or about 35 nm, such as greater than or about 40 nm, or such as less than or about 60 nm, such as less than or about 55 nm, such as less than or about 50 nm, such as less than or about 45 nm, such as less than or about 40 nm, or any ranges or values therebetween.

Regardless of the material and thickness of sacrificial layer 304, one or more junction materials 306 may be formed over sacrificial layer 304 at operation 202, as illustrated in FIG. 3B. In embodiments, a junction material 306 may be grown or deposited over sacrificial layer 304. In embodiments, the junction material 306 may be grown or deposited directly over sacrificial layer 304 (e.g., no intervening layers between sacrificial layer 304 and junction material 306) or may be grown or deposited over one or more intervening layers (not shown). Nonetheless in embodiments, the junction material 306 may be any one or more of the substrate materials discussed above and may be individual selected to be the same or different than a material forming substrate 302. Furthermore, in embodiments, p-type or n-type doping may occur via blanket doping, dopant implant, or a modulated dopant profile, as well as other methods as known in the art.

However, in embodiments, the present technology has found that by including one or more dopants, a junction may be doped during epitaxial growth of the semiconductor structure 300. Such as process may be advantageous, as it removes the necessity for doping the junction after formation of one or more channels (discussed in greater detail below) or as part of backside processing. Thus, in embodiments, the junction material 306 may undergo blanket doping during the growth or deposition of the layer. For instance, in embodiments, the junction material 306 may be epitaxial silicon, and subjected to P+, P−, N+ and/or N− blanket doping. Blanket doping may be conducted as known in the art, such as by including the dopants during epitaxial growth. When the junction material 306 contains one or more dopants, the junction material 306 may serve as a source/drain region of structure 300.

Moreover, as discussed above, the present technology has found that by utilizing blanket doping during deposition or growth, a targeted and highly consistent doping level may be formed without requiring later junction processing. For instance, in embodiments, a junction material 306 may have a dopant concentration at any point along or within the junction material 306 that is greater than or about 50% of a target doping concentration of junction material 306, such as greater than or about 60%, such as greater than or about 70%, such as greater than or about 80%, such as greater than or about 85%, such as greater than or about 90%, such as greater than or about 92.5%, such as greater than or about 95%, such as greater than or about 97.5%, such as greater than or about 99%, such as greater than or about 99.5% of the average doping concentration of junction material 306, or any ranges or values therebetween. However, it should be clear that the, in embodiments, the target doping concentration may vary when travelling in a direction from substrate 302 towards channel material 308 (e.g. such as decrease, in embodiments). Thus, in embodiments, the highly consistent doping level may be in comparison to a target doping level in a corresponding horizontally extending layer of junction material. For instance, the present technology has surprisingly found that by forming the junction as part of a precursor structure 300, a respective layer or portion of the junction may have a highly consistent doping concentration and may exhibit little to no variation across the layer. Furthermore, the highly accurate doping is exhibited within a respective region or portion even when changing the target doping concentration as the junction is formed in a vertical direction. Thus, in embodiments, the above discussed values may be in relation to a point within a respective junction layer having a dopant concentration consistent with a target doping concentration for the respective layer or portion.

In embodiments, a channel material 308 may be deposited over junction material 306 at operation 203 as illustrated in FIG. 3C. In embodiments, the channel material 308 may be deposited directly over junction material 306 (e.g., no intervening layers between junction material 306 and channel material 308) or may be deposited over one or more intervening layers (not shown). Nonetheless in embodiments, the channel material 308 may be any one or more of the substrate materials discussed above and may be individual selected to be the same or different than a material forming substrate 302 and/or junction material 306.

However, in embodiments, channel material layer 308 may be formed from the same material as junction material 306, except that no dopant, or only very small levels, may be present. Thus, in such an embodiment, if epitaxial growth is utilized, the epitaxial growth may continue uninterrupted during the formation of junction material 306 and channel material 308, but no, or only very small levels, of dopant may be incorporated during growth of channel material 308. Nonetheless, as discussed above, in embodiments, other deposition methods may be utilized, such that a different material, a different process, or a combination thereof, occurs between junction material 306 and channel material 308. Regardless, in embodiments, the channel material 308 may be epitaxial grown silicon (or any of the other substrate materials discussed above) with a lower amount, or no, dopant present in the layer.

In embodiments, regardless of the material selected, the channel may be deposited to a height corresponding to a desired channel length. Thus, in embodiments, the channel may be deposited to a height, measured from junction material 306 to an end top surface of channel material 308, of greater than or about 10 nm, such as greater than or about 15 nm, such as greater than or about 20 nm, such as greater than or about 25 nm, such as greater than or about 30 nm, such as greater than or about 35 nm, such as greater than or about 40 nm, such as greater than or about 45 nm, such as greater than or about 50 nm, such as greater than or about 55 nm, such as greater than or about 60 nm, such as greater than or about 65 nm, such as greater than or about 70 nm, such as greater than or about 75 nm, such as greater than or about 80 nm, such as greater than or about 90 nm, such s greater than or about 100 nm, such as greater than or about 120 nm, such as greater than or about 140 nm, such as greater than or about 160 nm, such as greater than or about 180 nm, such as greater than or about 200 nm, such as greater than or about 220 nm, such as greater than or about 240 nm, or such as greater than or about 250 nm, or such as less than or about 250 nm, such as less than or about 200 nm, such as less than or about 150 nm, such as less than or about 100 nm, or any ranges or values therebetween.

In embodiments, a second junction material 310 may be grown or deposited over channel material 308 at operation 204, as illustrated in FIG. 3D. In embodiments, the second junction material 310 may be grown or deposited directly over channel material layer 308 (e.g., no intervening layers between channel material layer 308 and second junction material 310) or may be grown or deposited over one or more intervening layers (not shown). Nonetheless in embodiments, the second junction material 310 may be any one or more of the substrate materials discussed above and may be individual selected to be the same or different than a material forming substrate 302, junction material 306, and/or channel material layer 308. Furthermore, in embodiments, p-type or n-type doping may occur via blanket doping, dopant implant, or a modulated dopant profile, as well as other methods as known in the art.

In embodiments, the second junction material 310 may undergo blanket doping during the growth or deposition of the layer. For instance, in embodiments, the second junction material 310 may be epitaxial silicon and subjected to P+, P−, N+ and/or N− blanket doping. In embodiments, the doping of second junction material 310 may be the same or different than junction material 306. Blanket doping may be conducted as known in the art, such as by including the dopants during epitaxial growth. When the second junction material 310 contains one or more dopants, the second junction material 310 may serve as a second source/drain region of structure 300.

Furthermore, as discussed above, the present technology has found that by utilizing blanket doping during deposition or growth, a targeted and highly consistent doping level may be formed. For instance, in embodiments, a second junction material 310 may have a dopant concentration at any point along or within the second junction material 310 that is greater than or about 50% of an average doping concentration of second junction material 310, such as greater than or about 60%, such as greater than or about 70%, such as greater than or about 80%, such as greater than or about 85%, such as greater than or about 90%, such as greater than or about 92.5%, such as greater than or about 95%, such as greater than or about 97.5%, such as greater than or about 99%, such as greater than or about 99.5% of the average doping concentration of second junction material 310. In addition, the doping level may be within any one or more of the above ranges from a target doping level (e.g., an embodiment where the average doping concentration is the target concentration).

Furthermore, in embodiments, second junction material 310 may be formed from the same material as junction material 306. Thus, in such an embodiment, if epitaxial growth is utilized, the epitaxial growth may continue uninterrupted during the formation of junction material 306, channel material layer 308, and second junction material 310 but dopant may be incorporated during the junction material 306 and second junction material 310, but not during formation of channel material layer 308. Nonetheless, as discussed above, in embodiments, other deposition methods may be utilized, such that a different material, a different process, or a combination thereof, occurs between one or more of first channel material layer 306, channel material layer 308, and second junction material 310. Regardless, in embodiments, the second junction material 310 may be epitaxial grown silicon (or any of the other substrate materials discussed above) with an amount of dopant similar to, or generally equal to, junction material 306. Regardless, such a substrate formation process (or provided substrate therefrom) may allow for high aspect ratio structures or features, or other complex features (e.g., one or more turns or bends from a central access hole) to be obtained with highly consistent and targeted doping levels difficult to achieve using conventional processes.

However, in embodiments, the one or more channel material layers 306 may instead be formed of one material, such as any one or more of the substrate materials discussed above. In such an embodiments, the one or more channel material layers 306 may undergo source/drain formation as known in the art. Such as by utilizing one or more implants after formation of a trench isolation 414, discussed in greater detail below.

In embodiments, the semiconductor structure 300 illustrated in FIG. 3D may form a precursor structure discussed herein. Namely, a precursor structure as formed according the present technology may be carefully formed to provide for one or more self-aligned features. Nonetheless, in embodiments, the precursor semiconductor structure 300 may include forming a contact pad 312 over second junction material 310. Contact pad 312 may include one or more dielectric materials, such as an oxide containing material, a nitride containing material, or other materials as known in the art.

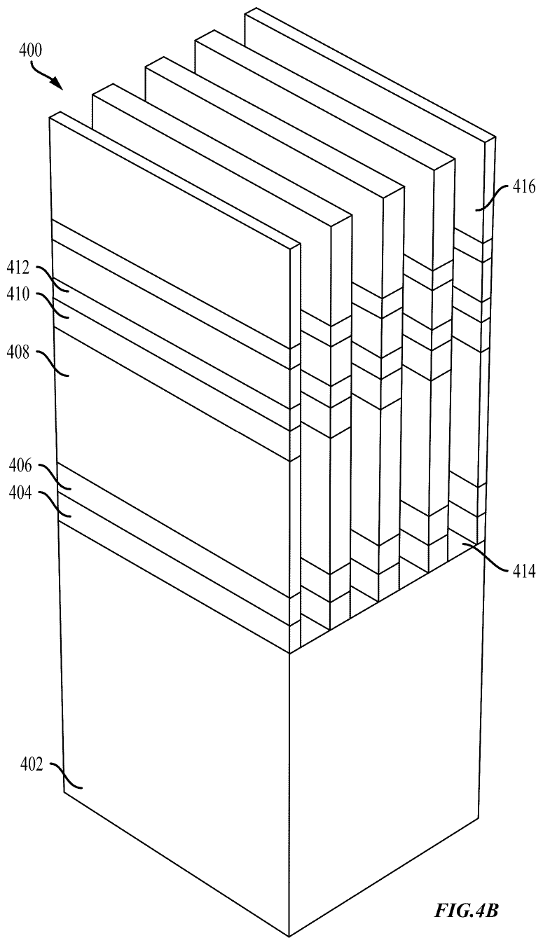

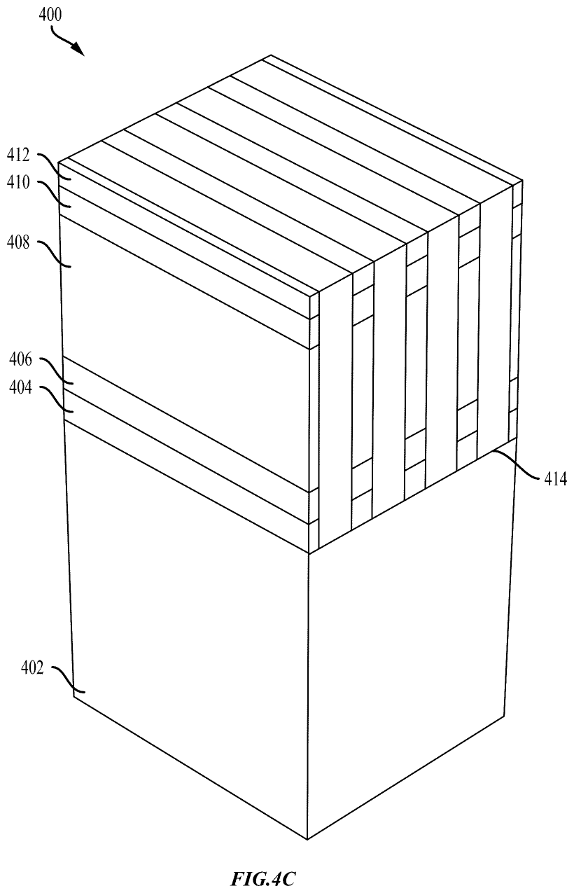

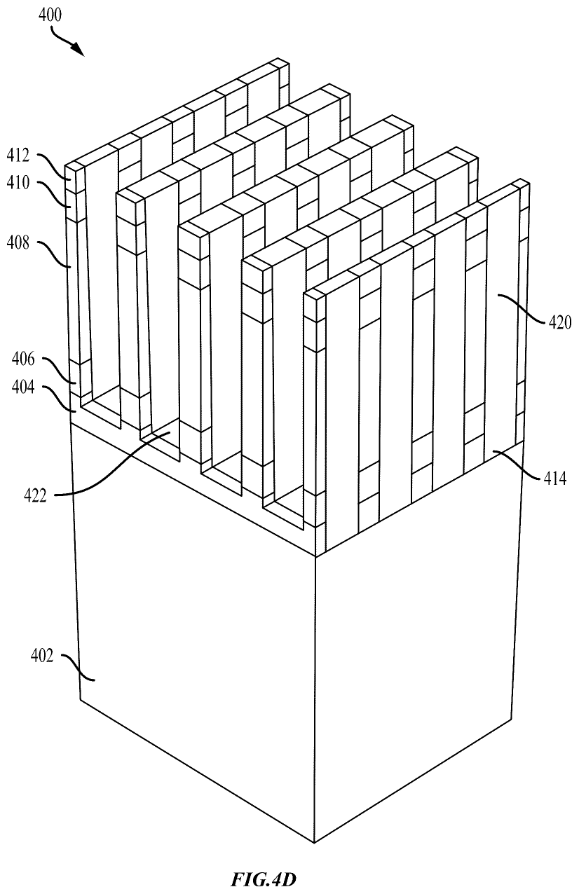

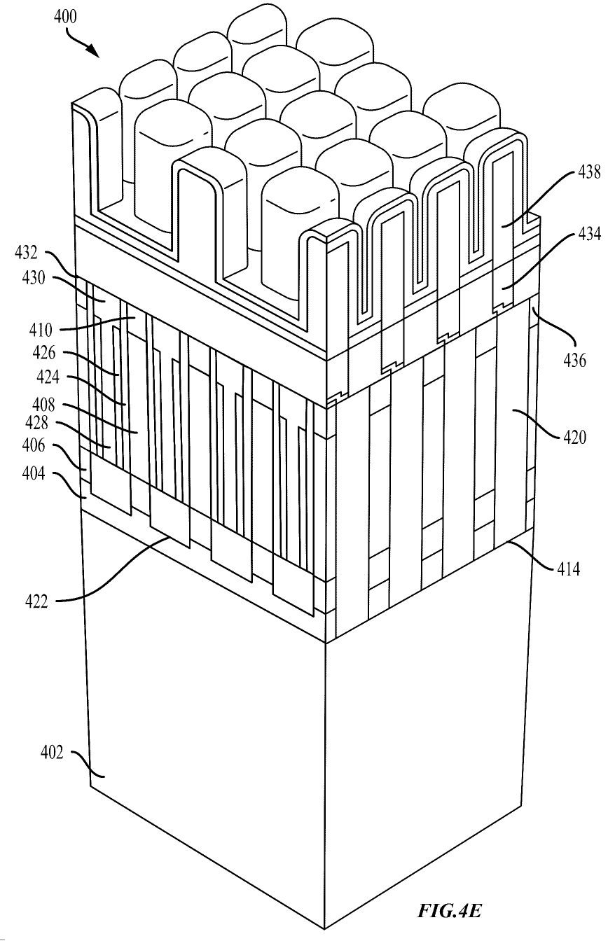

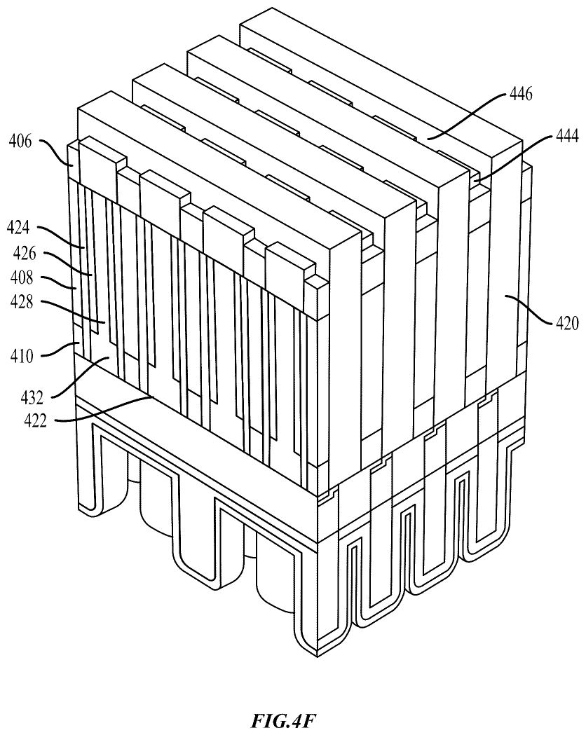

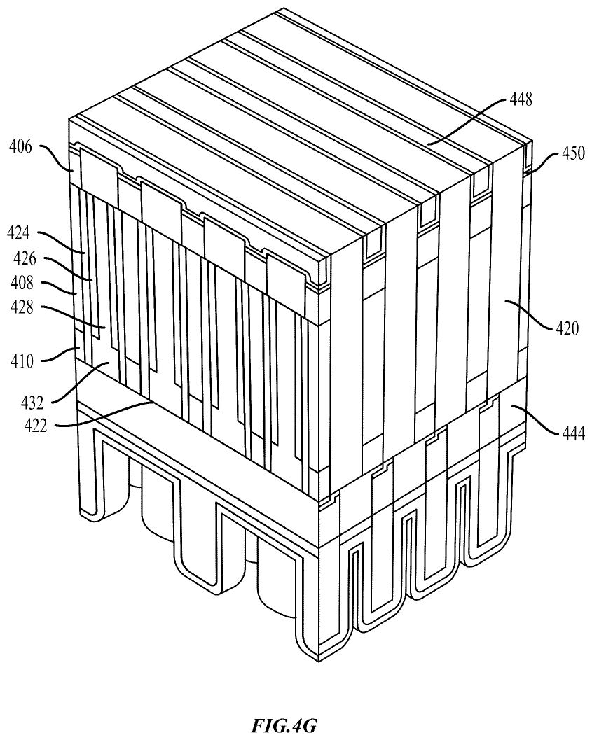

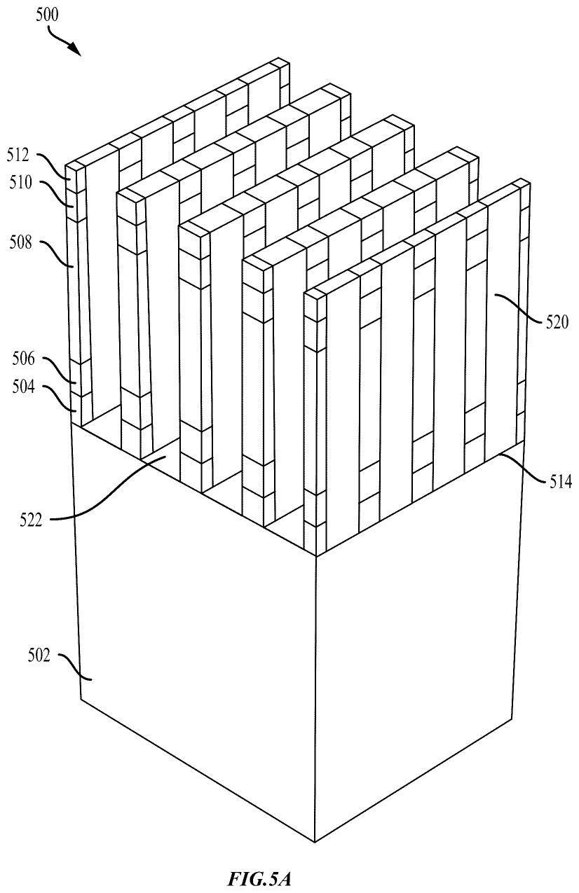

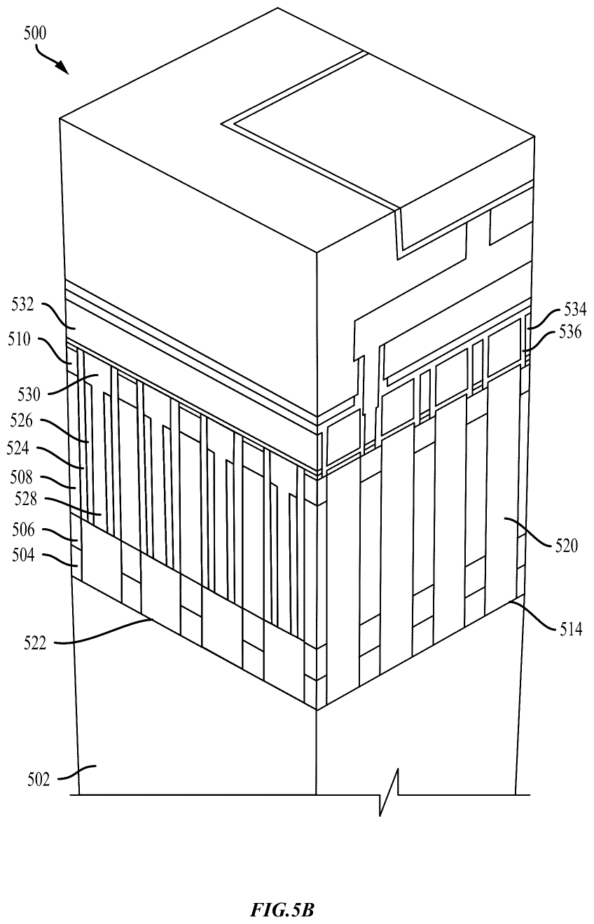

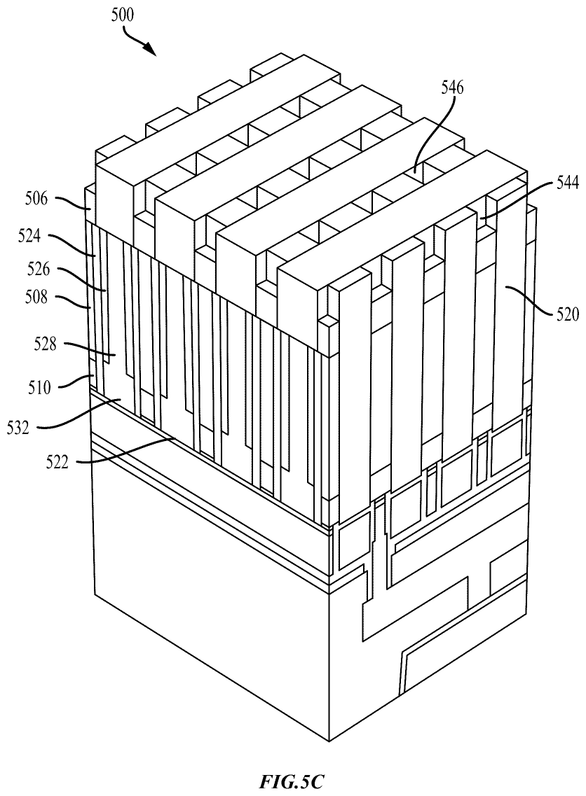

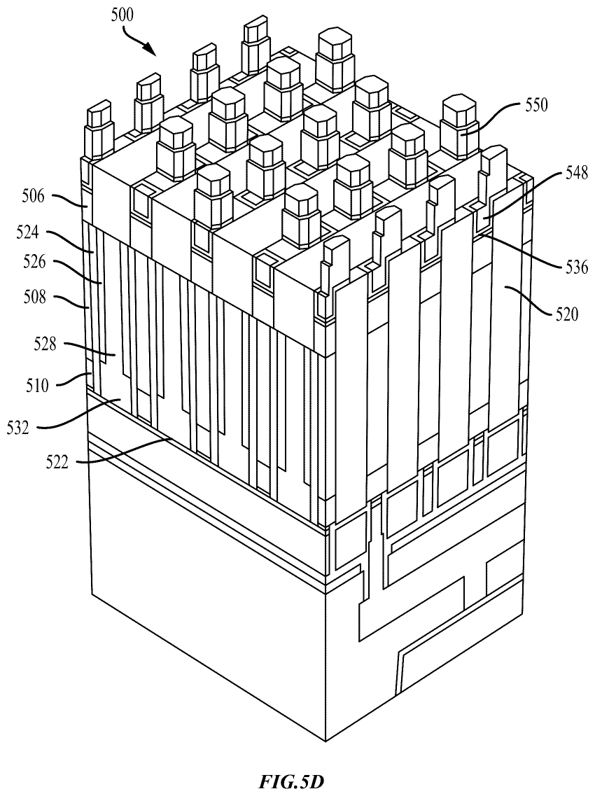

While it should be clear that the precursor semiconductor structure 300 may be utilized to advantageously form a variety of challenging structures, FIGS. 4A-4G and 5A-5D may illustrate exemplary structures, and methods of forming such structures, utilizing the precursor semiconductor structure 300 for illustration only. However, it should be clear that these examples are non-limiting and that further structures as well as methods of forming such structures from the precursors discussed above are contemplated.

Nonetheless, as illustrated in FIG. 4A, structure 400 may have one or more trench isolations 414 formed through junction material 406, channel material 408, and second junction material 410. Such a trench may be formed as known in the art, such as by patterning and etching, such as by utilizing mask 416 and any etching process known in the art. However, in embodiments, etching of trench isolation 414 may be a two-step operation as illustrated in FIGS. 4A and 4B. Namely, the trench 414 may be initially etched according to any one or more methods as known in the art, and then a second etch operation selective to the sacrificial material 404 may be conducted. In such a manner, a highly aligned and even trench 414 may be formed in structure 400.

Namely, in addition to the benefits discussed above, by utilizing such a selective etch, excellent depth control may be obtained. Furthermore as will be discussed in greater detail in regards to the word line etch in FIG. 3D, by utilizing a sacrificial material with a different etch selectivity than the channel and/or junction materials, a high tailored etch depth may be achieved without additional lithography or patterning processes.

As illustrated in the exemplary embodiment of FIG. 4C, the trench 414 may be filled with an insulative material 420, such as a dielectric material. In such a manner, the insulative material 420 may electrically isolate and support the metallized feature (discussed in greater detail below). Nonetheless, in embodiments, the insulative material 420 may be a dielectric material, such as an oxide containing material, a nitride containing material, or a combination thereof. In embodiments, insulative material 420 may include one or more of a silicon oxide, silicon oxycarbide, silicon oxynitride, silicon oxycarbonitride, combinations thereof, or other dielectric material as known in the art, formed utilizing any fill methods discussed above and as known in the art.

Turning to FIG. 4D, in the illustrated embodiment, one or more word line trenches 422 may be formed at operation 205. As FIGS. 4A-4G may illustrate an exemplary embodiment for forming a metallized bitline, the word line trench 422 may advantageously extend vertically to sacrificial material 404. However, it should be understood that, in embodiments, a one or two step etch may be utilized that forms the word line trench through sacrificial material 404 to substrate 402. Regardless, in the illustrated embodiment, by utilizing a material with an etch selectivity to junction material 406, channel material 408, and junction material 410, the sacrificial material 404 may be retained during word line trench 422 formation. This may allow the space to be retained for a self-aligned bitline to be formed without requiring additional patterning or lithography operations, as will be discussed in greater detail below.

In embodiments, after trench 422 formation one or more additional components associated with a 4F2 dynamic random-access memory (DRAM) device may be formed, as illustrated in FIG. 4E. For instance, a gate dielectric 424 may be formed generally around a perimeter of trench 422. Additionally or alternatively, if silicon is utilized as the channel material 408, the trench 422 may be subjected to in-situ steam generation to provide a silicon oxide as the gate dielectric 424 around the perimeter of trench 422. Nonetheless, in embodiments, the gate dielectric 424 may be a dielectric material, such as a silicon oxide, silicon oxycarbide, silicon oxynitride, silicon oxycarbonitride, combinations thereof, or other dielectric material as known in the art, formed utilizing any fill methods discussed above and as known in the art.

Moreover, as illustrated in FIG. 4E, in embodiments, a gate metal 426 may be formed within trench 422 along gate dielectric 424. The gate metal 426 may be a conductive material having a low resistivity, such as tungsten, molybdenum, titanium, zirconium, nickel, hafnium, cobalt, tin, tantalum, platinum, iron, niobium, palladium, a metal-containing species thereof, alloys thereof, or combinations thereof, deposited by any one or more methods as known in the art or as discussed above. Nonetheless, as shown, the gate metal 426 may be bottom punched to remove gate metal 426 from a bottom surface of the trench 422, separating adjacent gates 426.

After punching, an insulative material 428 may be filled in trench 422 between adjacent gates 426. Nonetheless, in embodiments, the insulative material 428 may be a dielectric oxide, such as one or more of a silicon oxide, silicon oxycarbide, silicon oxynitride, silicon oxycarbonitride, combinations thereof, or other dielectric material as known in the art, formed utilizing any fill methods discussed above and as known in the art.

Furthermore, as shown, an insulative plug 430 may be formed between gate(s) 426 and upper surface 432 of channel 408. The plug 430 may be formed from any insulative material as known in the art, such as one or more dielectric materials including silicon nitride, a silicon oxynitride, silicon dioxide, or other similar materials. Although the description herein will regularly discuss silicon oxide or silicon nitride as a dielectric material and/or a spacer material, it is to be understood that any number of dielectric materials may be used in embodiments of the present technology, and the present technology should not be limited to any particular dielectric material in which features may be formed.

In embodiments, junction 410 may undergo a metallization process, such as silicidation to form a metallized interface over junction 410. For instance, a metal layer may be applied over junction 410 which is subsequently exposed to a silicidation process, forming metallized contact 436. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Thus, the resulting interface may be a metallized layer of any one or more of the above metals and the channel material, such as silicon. In such an example only, the interface layer may be a titanium silicide, molybdenum silicide, hafnium silicide, or a combination thereof.

Nonetheless, one or more storage node contacts 434 may be formed over the metallized contacts 436. In embodiments, the metal may be tungsten, molybdenum, titanium, zirconium, nickel, hafnium, cobalt, tin, tantalum, platinum, iron, niobium, palladium, a metal-containing species thereof, alloys thereof, or combinations thereof. The storage node contact metal may be selected to be the same material or a different material than gate metal 426 discussed above. As illustrated, in embodiments, a storage node landing pad 438 may also be formed over storage node contact 434.

After formation of the storage node contact features, the frontside DRAM capacitor may be complete, in embodiments. However, in embodiments, as discussed above, the structure 400 may be subjected to one or more further operations, which may also be considered to be frontside operations.

Nonetheless, at operation 206, the structure 400 may be rotated 180 degrees (referred to as “flipped” herein), such that the previous upper surface of structure 400 may now be oriented as a bottom surface. However, as will be discussed in greater detail below, such a step may not be necessary to access sacrificial layer 404, in embodiments. Nonetheless, as operation 206, access to the sacrificial material 404 may be provided so as to selectively remove sacrificial layer 404. As illustrated in FIG. 4F, such access may be provided by thinning substrate 402 from the backside. In embodiments, all or a portion of substrate 402 may be removed from the backside in order to access sacrificial material 404.

However, as known in the art, sacrificial materials, such as SiGe are highly selective. Thus, in embodiments, operation 206 may include providing one or more access holes through substrate 402 to selectively etch sacrificial material 404, instead of fully removing substrate 402. Additionally or alternatively, a side access, such as from side 444 may be provided or expanded alone or in combination with one or more access holes. Regardless of the method used, it should be clear that sacrificial material 404 is selected to have an etch specificity that allows sacrificial material 404 to be etched selectively to insulative layer 420 and 428, as well as junction material 406, channel material 408, and junction material 410. Thus, insulative layer 420 remains disposed between adjacent void spaces 446 formed from removal of sacrificial material 404. Nonetheless, while examples have been provided, it should be clear that sacrificial material 404 may be removed utilizing any methods as known in the art at operation 206 and as illustrated in FIG. 4F, where sacrificial material 404 has been removed, providing a void space 446 defined by insulative material 420 and junction material 406.

Referring to the illustrated embodiment in FIG. 4G, at operation 207, the void space 446 may allow access to a first source/drain region (e.g., junction material 406 in the illustrated embodiment). The first source/drain region 406 may undergo a metallization process, such as silicidation to form a metallized interface 450 between void space 446 and first source/drain region 406. For instance, a metal layer may be applied over first source/drain 406 which is subsequently exposed to a silicidation process. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Thus, the resulting interface may be a metallized layer of any one or more of the above metals and the channel material, such as silicon. In such an example only, the interface layer may be a titanium silicide, molybdenum silicide, hafnium silicide, or a combination thereof.

Nonetheless, in embodiments, the void space 446 may then be filled with a metal bit line 448 material. In embodiments, the metal may be tungsten, molybdenum, titanium, zirconium, nickel, hafnium, cobalt, tin, tantalum, platinum, iron, niobium, palladium, a metal-containing species thereof, alloys thereof, or combinations thereof. The bit line metal may be selected to be the same material or a different material than gate metal 426 discussed above. As shown in the illustrated embodiments, the bit line metal 448 may be filled in void space 446 in a highly aligned (e.g., self-aligned) manner. Thus, in embodiments, the metal bit line 448 may be disposed directly above the respective channel 408 without requiring any masking or photoresist operations.

However, the present technology has also surprisingly found that the process and methods discussed herein also allow for the inclusion of a bit line spacer or air gap. For instance, in embodiments, the bit line metal 448 may be filled in to void space 446 such that the bit line metal 448 at least partially intersects source/drain region 406. For instance, in embodiments, the bit line metal 448 may be offset, or have a smaller width than the respective overlying channel 408, such that the bit line is offset (or has a smaller width) by about 10% to about 90% of a width of the respective channel, such as greater than or about 15%, such as greater than or about 20%, such as greater than or about 30%, such as greater than or about 40%, such as greater than or about 50%, such as greater than or about 60%, such as greater than or about 70%, such as greater than or about 80%, such as greater than or about 85%, or such as less than or about 85%, less than or about 80%, less than or about 70%, less than or about 60%, less than or about 50%, less than or about 40%, less than or about 30%, less than or about 20%, less than or about 15%, or any ranges or values therebetween. The spacer mentioned above can be removed downstream to form an air gap as needed.

In embodiments, the insulative material 420 may be filled or etched after filling in trench 414 in such a manner that only a portion of the trench 414 is filled with the insulative material 420. Thus, the metal bit line 448 may be filled such that the bit line 448 is slightly off-centered from the respective channel, but still supported by insulative layers 420. In such an embodiment, the metal bit lines 448 may be considered to be a folded cell. Nonetheless, it should be clear that, whether the offset (or reduced width), is utilized alone or in combination with a partially filled trench 414, at least a portion of the bit line metal 448 intersects with the respective channel according to the above ratios. Furthermore, in such an embodiment, the sacrificial material 404 may be accessed from the partially filled trench 414. Thus, in embodiments, the removal of the sacrificial material 404 and filling of bit line metal 448 may be considered to be a front side process, and the remainder of trench 414 may be filled with an insulative material after formation of the metal bit line 448.

Nonetheless, after filling, the bit line 448 may be optionally further metallized. Regardless, the structure 400 may re-enter a normal process flow for further processing, such as polishing, additions or interconnects, and the like for a vertical cell DRAM array, such as a 4F² DRAM array. For instance, the semiconductor structure 400 may undergo contact redistribution, bonding pad formation, and/or copper contact formation. Notwithstanding the additional processing, the semiconductor structure may exhibit a drastically improved bit line resistivity and alignment with little to no damage generally associated with conventional techniques.

Referring next to FIG. 5A, an example of forming one or more self-aligned storge nodes may be provided. The structure 500 illustrated in FIG. 5A may undergo operations similar to that discussed above in regards to FIGS. 4A to 4C, at which point one or more operations or process steps may diverge. While it should be understood that different processing operations may occur prior to FIG. 5A, in embodiments, FIG. 5A may be formed from one or more operations that occur in a similar fashion to FIGS. 4A to 4C through operation 204, and may therefore not be repeated for clarity. While it should be clear that the precursor semiconductor structure 300 may be utilized to advantageously form a variety of challenging structures, FIGS. 5A-5D may illustrate exemplary structures, and methods of forming such structures, utilizing the precursor semiconductor structure 300 for illustration only. However, it should be clear that these examples are non-limiting and that further structures as well as methods of forming such structures from the precursors discussed above are contemplated.

Turning to FIG. 5A, in embodiments, one or more word line trenches 522 may be formed at operation 205. As FIGS. 5A-5D may illustrate forming one or more metallized storage node contacts, the word line trench 522 may advantageously extend vertically through sacrificial material 504. In embodiments, a one or two step etch may be utilized that forms the word line trench through sacrificial material 504 to substrate 502, separating adjacent portions of sacrificial layer 504 in a spaced apart and isolated manner below a respective junction 506 and channel 508. As illustrated the sacrificial material 504 may be neatly aligned with the respective channel, allowing a later formed storage node contact to be precisely formed in a self-aligned manner. Regardless, in the illustrated embodiment, by utilizing a material with an etch selectivity to junction material 406, channel material 408, and junction material 410, the sacrificial material 404 may be retained during a first etch of wordline trench 522 formation. This may allow a highly controlled depth of the trench 522 to be achieved without further processing.

After trench 522 formation, in embodiments, one or more additional components associated with a 4F2 dynamic random-access memory (DRAM) device may be formed, as illustrated in FIG. 5B. For instance, a gate dielectric 524 may be formed generally around a perimeter of trench 522. Additionally or alternatively, if silicon is utilized as the channel material 508, the trench 522 may be subjected to in-situ steam generation to provide a silicon oxide as the gate dielectric 524 around the perimeter of trench 522. Nonetheless, in embodiments, the gate dielectric 524 may be a dielectric material, such as a silicon oxide, silicon oxycarbide, silicon oxynitride, silicon oxycarbonitride, combinations thereof, or other dielectric material as known in the art, formed utilizing any fill methods discussed above and as known in the art.

Moreover, as illustrated in FIG. 5B, in embodiments, a gate metal 526 may be formed within trench 522 along gate dielectric 524. The gate metal 426 may be a conductive material having a low resistivity, such as tungsten, molybdenum, titanium, zirconium, nickel, hafnium, cobalt, tin, tantalum, platinum, iron, niobium, palladium, a metal-containing species thereof, alloys thereof, or combinations thereof, deposited by any one or more methods as known in the art or as discussed above. Nonetheless, as shown, the gate metal 526 may be bottom punched to remove gate metal 526 from a bottom surface of the trench 522, separating adjacent gates 526.

In embodiments, after punching, an insulative material 528 may be filled in trench 522 between adjacent gates 526. Nonetheless, in embodiments, the insulative material 528 may be a dielectric oxide, such as one or more of a silicon oxide, silicon oxycarbide, silicon oxynitride, silicon oxycarbonitride, combinations thereof, or other dielectric material as known in the art, formed utilizing any fill methods discussed above and as known in the art.

Furthermore, as shown, an insulative plug 530 may be formed between gate(s) 526 and upper surface 532 of channel 508. The plug 530 may be formed from any insulative material as known in the art, such as one or more dielectric materials including silicon nitride, a silicon oxynitride, silicon dioxide, or other similar materials. Although the description herein will regularly discuss silicon oxide or silicon nitride as a dielectric material and/or a spacer material, it is to be understood that any number of dielectric materials may be used in embodiments of the present technology, and the present technology should not be limited to any particular dielectric material in which features may be formed.

In embodiments, junction 510 may undergo a metallization process, such as silicidation to form a metallized interface over junction 510. For instance, a metal layer may be applied over junction 510 which is subsequently exposed to a silicidation process, forming metallized contact 536. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Thus, the resulting interface may be a metallized layer of any one or more of the above metals and the channel material, such as silicon. In such an example only, the interface layer may be a titanium silicide, molybdenum silicide, hafnium silicide, or a combination thereof.

Nonetheless, in embodiments, one or more bit lines 534 may be formed over the metallized contacts 536. In embodiments, the metal may be tungsten, molybdenum, titanium, zirconium, nickel, hafnium, cobalt, tin, tantalum, platinum, iron, niobium, palladium, a metal-containing species thereof, alloys thereof, or combinations thereof. The bit line metal may be selected to be the same material or a different material than gate metal 526 discussed above.

After formation of bit line, the frontside DRAM capacitor may be complete. However, in embodiments, as discussed above, the structure 400 may be subjected to one or more further operations, which may also be considered to be frontside operations.

Nonetheless, at operation 206, the structure 500 may be rotated 180 degrees (referred to as “flipped” herein), such that the previous upper surface of structure 500 may now be oriented as a bottom surface. However, as discussed above, such a step may not be necessary to access sacrificial layer 504, in embodiments. Nonetheless, as operation 206, access to the sacrificial material 504 may be provided so as to selectively remove sacrificial layer 504. As illustrated in FIG. 5C, such access may be provided by thinning substrate 502 from the backside. In embodiments, all or a portion of substrate 502 may be removed from the backside in order to access sacrificial material 504.

However, as known in the art, sacrificial materials, such as SiGe are highly selective. Thus, in embodiments, operation 206 may include providing one or more access holes through substrate 502 to selectively etch sacrificial material 504, instead of fully removing substrate 502. Additionally or alternatively, a side access, such as from side 544 may be provided or expanded alone or in combination with one or more access holes. Regardless of the method used, it should be clear that sacrificial material 504 is selected to have an etch specificity that allows sacrificial material 504 to be etched selectively to insulative layer 520 and 528, as well as junction material 506, channel material 508, and junction material 510. Thus, insulative layer 520 remains disposed between adjacent void spaces 546 formed from removal of sacrificial material 404. Nonetheless, while examples have been provided, it should be clear that sacrificial material 504 may be removed utilizing any methods as known in the art at operation 206 and as illustrated in FIG. 5C, where sacrificial material 504 has been removed, providing one or more void spaces 546 defined by insulative material 520 and junction material 506.

Referring to FIG. 5D, in embodiments, at operation 207, the void space 546 may allow access to a first source/drain region (e.g., junction material 506 in the illustrated embodiment). The first source/drain region 506 may undergo a metallization process, such as silicidation to form a metallized interface 536 between void space 546 and first source/drain region 506. For instance, a metal layer may be applied over first source/drain 506 which is subsequently exposed to a silicidation process. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Thus, the resulting interface may be a metallized layer of any one or more of the above metals and the channel material, such as silicon. In such an example only, the interface layer may be a titanium silicide, molybdenum silicide, hafnium silicide, or a combination thereof.

Nonetheless, the void space 546 may then be filled with a metal storage node contact 548 material. In embodiments, the metal may be tungsten, molybdenum, titanium, zirconium, nickel, hafnium, cobalt, tin, tantalum, platinum, iron, niobium, palladium, a metal-containing species thereof, alloys thereof, or combinations thereof. The storage node contact metal may be selected to be the same material or a different material than gate metal 526 discussed above. As shown in the illustrated embodiments, the storage node contact metal 548 may be filled in void space 546 in a highly aligned (e.g., self-aligned) manner. Thus, in embodiments, the storage node contact 548 may be disposed directly above the respective channel 508 without requiring any masking or photoresist operations.

In embodiments, after filling, the storage node contact 548 may be optionally further metallized. Regardless, the structure 500 may re-enter a normal process flow for further processing, such as polishing, additions or interconnects, and the like for a vertical cell DRAM array, such as a 4F² DRAM array. For instance, the semiconductor structure 500 may undergo contact redistribution, bonding pad formation, and/or copper contact formation, including landing pad 550 formation. Notwithstanding the additional processing, the semiconductor structure may exhibit a drastically improved bit line and storage node contact resistivity and alignment with little to no damage generally associated with conventional techniques.

It should be appreciated that the specific steps illustrated in the figures provide particular methods of forming 4F² DRAM arrays according to various embodiments. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications, as various operations discussed herein may be suitable for other devices. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMS, EEPROMs, magnetic or optical cards, flash memory, or other types of machine-readable mediums suitable for storing electronic instructions. Alternatively, the methods may be performed by a combination of hardware and software.

1-11. (canceled)

12. A vertical cell dynamic random-access memory (DRAM) array, comprising:
a plurality of metallized bit lines arranged in a first horizontal direction;
a plurality of word lines arranged in a second horizontal direction;
a plurality of channels extending in a vertical direction that is generally orthogonal to the first horizontal direction and the second horizontal direction such that the plurality of metallized bit lines intersect with a source/drain region of the plurality of channels, and the plurality of word lines intersect with gate regions of the plurality of channels; and
a dielectric material spacer disposed between adjacent bit lines of the plurality of bit lines.

13. The vertical cell dynamic random-access memory (DRAM) array of claim 12, wherein the dielectric material spacer comprises a dielectric oxide.

14. The vertical cell dynamic random-access memory (DRAM) array of claim 12, wherein at least a portion of the metallized bit lines are offset from a respective channel of the plurality of channels by about 10% to less than or about 90% of a width of the respective channel.

15. The vertical cell dynamic random-access memory (DRAM) array of claim 14, wherein at least a portion of the dielectric material spacers at least partially intersect with a source/drain region of the plurality of channels.

16. The vertical cell dynamic random-access memory (DRAM) array of claim 12, wherein the bit line is a self-aligned bit line disposed below a single crystalline channel.

17. The vertical cell dynamic random-access memory (DRAM) array of claim 12, further comprising one or more metallized storage node contacts disposed on a top end of the plurality of channels.

18. A method of forming a vertical cell dynamic random-access memory (DRAM) array, comprising:
providing a substrate, comprising:
a sacrificial material over a substrate material, and
one or more channel materials disposed over the sacrificial material,
etching the substrate to form one or more shallow trench isolations and a plurality of vertically extending channels having at least a first source/drain region;
forming a dielectric material in the one or more of the shallow trench isolations;
removing at least a portion of the sacrificial material, forming a void space that at least partially intersects with a portion of the first source/drain region of the vertically extending channels; and
forming a metallized bit line in the void space.

19. The method according to claim 18, further comprising forming a word line in a word line trench, wherein the word line intersects with a gate region of the plurality of vertically extending channels.

20. The method according to claim 18, wherein the portion of the sacrificial material is removed through one or more access holes.

21. The method according to claim 18, wherein the portion of the sacrificial material is removed through an exposed region at a substrate backside or a side surface.

22. The method according to claim 18, further comprising reducing a thickness of the substrate material prior to removing the at least a portion of the sacrificial material.

23. The method according to claim 18, further comprising removing all of the sacrificial material.

24. The method according to claim 18, wherein the one or more channel materials include a doped channel material and an undoped channel material.

25. The method according to claim 18, further comprising forming one or more of the plurality of vertically extending channel by depositing a doped channel material over the sacrificial material, depositing an undoped channel material over the doped channel material, and depositing a second doped channel material over the undoped channel material.

26. The method according to claim 18, further comprising flipping the substrate, and removing all or a portion of the substrate prior to removing the sacrificial material.

27. The method of claim 18, further comprising siliciding the first source/drain region prior to forming the metallized bit line.

28. The method of claim 18, wherein the metallized bit line comprises tungsten, molybdenum, titanium, zirconium, nickel, hafnium, cobalt, tin, tantalum, platinum, iron, niobium, palladium, a metal-containing species thereof, alloys thereof, or combinations thereof.

29-37. (canceled)

38. The method of claim 18, further comprising etching the one or more shallow trench isolations to a second depth, greater than a first depth.

39. The method of claim 38, wherein etching the one or more shallow trench isolations to a second depth comprises etching a second portion of the sacrificial material.

40. The method of claim 39, wherein the sacrificial material comprises an etch selectivity to the first source/drain region and/or the plurality of vertically extending channels.
